(19) United States
(12) Patent Application Publication
(10) Pub. No.: US 2014/0174793 A1
(43) Pub. Date: Jun. 26, 2014

(54) PRINTED CIRCUIT BOARD AND METHOD FOR MANUFACTURING THE SAME

(71) Applicant: SAMSUNG ELECTRO-MECHANICS CO., LTD., Suwon (KR)

(72) Inventors: Chang Gun Oh, Suwon (KR); Ho Sik Park, Suwon (KR); Hwa Sub Oh, Suwon (KR)

(73) Assignee: SAMSUNG ELECTRO-MECHANICS CO., LTD., Suwon (KR)

(21) Appl. No.: 14/038,509

(22) Filed: Sep. 26, 2013

(30) Foreign Application Priority Data
Dec. 26, 2012 (KR) 10-2012-0152982
Apr. 30, 2013 (KR) 10-2013-0048708

(51) Int. Cl. H05K 1/02; H05K 3/40

(52) U.S. Cl. CPC H05K 1/0206; H05K 3/4038
USPC 174/252; 29/852

(57) ABSTRACT

Disclosed herein are a printed circuit board and a method for manfuacturing the same, the printed circuit board including: a base substrate having circuit patterns; and heat radiating vias having a donut shape, formed in the base substrate, so that the heat radiation efficiency may be improved by increasing the area of the heat radiating via.

### CROSS REFERENCE TO RELATED APPLICATION

This application claims the benefit of Korean Patent Application No. 10-2012-0152982, filed Dec. 26, 2012, entitled “Printed Circuit Board and Method for Manufacturing Thereof”, and Korean Patent Application No. 10-2013-0048708, filed Apr. 30, 2013, entitled “Printed Circuit Board and Method for Manufacturing Thereof”, which are hereby incorporated by reference in their entireties into this application.

### BACKGROUND OF THE INVENTION

1. Technical Field

The present invention relates to a printed circuit board and a method for manufacturing the same.

2. Description of the Related Art

In the case of an RF module used in mobile communication, operations thereof become rapidly deteriorated as a semiconductor chip rises in temperature due to the heat generated therefrom. Therefore, in order to allow a substrate which has a semiconductor chip for an RF module mounted thereon to effectively remove the heat generated from the semiconductor chip, many heat radiating vias are formed on a lower part of a die attach pad on which the semiconductor is mounted for the purpose of heat radiation, and copper (Cu) having excellent conductivity fills inside of the heat radiating vias by using a plating method.

Recently, as the semiconductor chip has an increase in use frequency, improvement in function, and a decrease in size, the heat generated from the semiconductor chip becomes a large problem, which leads to an increase in request for heat radiation. Due to this request, an attempt is made to increase a size of the heat radiating via in the substrate for an RF module to thereby promptly and efficiently remove more heat. However, in the case where the size of the heat radiating via is 100 μm or greater, if a plating process is performed by a copper filling plating method of the prior art, a large dimple may occur, and thus a multilayer substrate has difficulty in forming a stack via, and if the dimple is exposed to an outermost layer, this may cause a problem in mounting the semiconductor chip.

Patent Document 1 shown in the section of Prior Art Document is directed to a printed circuit board and a method for manufacturing the same, the printed circuit board including a base substrate having an insulating layer divided into a circuit region provided in a center thereof and a dummy region provided at an outer region of the circuit region; a circuit layer formed in the circuit region of the insulating layer and having circuit patterns and vias; and heat radiating patterns formed by filling cavities provided in the dummy region of the insulating layer.

The foregoing printed circuit board and method for manufacturing the same disclose contents associated with a heat radiating via, but fail to suggest measures for increasing the area of the heat radiating via to thereby improve operations of the RF module.

### PRIOR ART DOCUMENT

### Patent Document

(Patent Document 1) Japanese Patent Laid-Open Publication No. 2005-26368

### SUMMARY OF THE INVENTION

The present invention has been made in an effort to provide a printed circuit board and a method for manufacturing the same, capable of increasing the area of a heat radiating via to thereby improve heat radiation efficiency.

According to a preferred embodiment of the present invention, there is provided a printed circuit board, including: a base substrate having circuit patterns; and heat radiating vias having a donut shape, formed in the base substrate.

Here, a center of the heat radiating via may be formed of an insulating layer and an outside of the insulating layer may be surrounded by a plating at a predetermined space.

Here, a diameter of the heat radiating via may be narrower from an upper portion toward a lower portion of the base substrate.

Here, a spaced distance between an inside wall and an outside wall of the heat radiating via may be narrower from an upper portion toward a lower portion thereof.

The base substrate may have one or more heat radiating vias formed thereon.

Here, a plurality of heat radiating vias may be formed on the same line of the base substrate and classified into a plurality of groups while at least two of the plurality of heat radiating vias overlap each other for each group.

According to another preferred embodiment of the present invention, there is provided a method for manufacturing a printed circuit board, the method including: preparing a base substrate having circuit patterns; and forming heat radiating vias having a donut shape in the base substrate.

The forming of the heat radiating vias may include: preparing an etching resist, having openings formed in the donut shape, on the base substrate; etching the base substrate to form heat radiating via holes having a donut shape; and plating inside of the heat radiating via holes to form heat radiating vias.

Here, a diameter of the heat radiating via hole may be narrower from an upper portion toward a lower portion of the base substrate.

Here, in the forming of the heat radiating vias, a spaced distance between an inside wall and an outside wall of each of the heat radiating vias may be narrower from an upper portion toward a lower portion thereof.

Here, in the forming of the heat radiating vias, one or more heat radiating vias may be formed.

Here, in the forming of the heat radiating vias, a plurality of heat radiating vias may be formed on the same line of the base substrate and classified into a plurality of groups while at least two of the plurality of heat radiating vias overlap each other for each group.

The method may further include after the preparing of the base substrate, forming vias.

The forming of the vias and the forming of the heat radiating vias may be simultaneously performed.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a cross-sectional view of a printed circuit board according to a preferred embodiment of the present invention;

FIG. 2 shows a plane view (a) and a cross-sectional view (b), showing a heat radiating via according to the preferred embodiment of the present invention;

FIG. 3 is a plane view showing an arrangement state of heat radiating vias according to the prior art;

FIG. 4 is a plane view showing an arrangement state of heat radiating vias according to the preferred embodiment of the present invention;

FIG. 5 is a plane view showing an arrangement state of heat radiating vias according to another preferred embodiment of the present invention; and

FIGS. 6 to 13 are exemplified views showing a method for manufacturing a printed circuit board according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

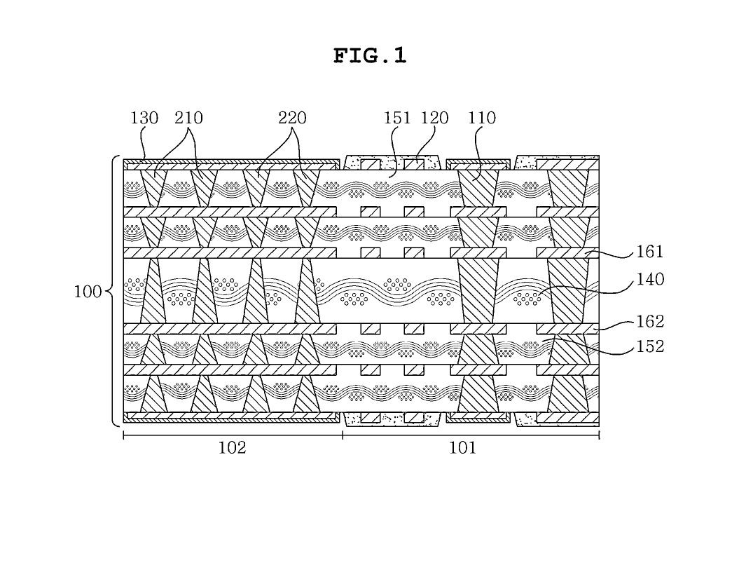

FIG. 1 is a cross-sectional view of a printed circuit board according to a preferred embodiment of the present invention. Referring to FIG. 1, a printed circuit board according to a preferred embodiment of the present invention may include a base substrate 100 and heat radiating vias 210 and 220, and may be exemplified with a six-layer RF substrate.

The base substrate 100 has a structure where inner layer circuit patterns 161 and 162 and insulating layers 151 and 152 are stacked based on a core layer 140. In addition, circuit patterns 110 and 120 are formed on the base substrate 100 outside the insulation layer 151 and 152. However, the base substrate 100 exemplified in FIG. 1 shows the core layer 140 and the inner layer circuit patterns 161 and 162, but need not include all of them, and all-structured substrates known in the art may be employed.

Here, a solder resist layer may be used for the insulating layers 151 and 152, or a composite polymer resin generally used as an interlayer insulation material may be used therefor. For example, a prepreg may be employed for the insulating layers 151 and 152 to manufacture a thinner printed circuit board, or an Ajinomoto Build up Film (ABF) may be employed for the insulating layers 151 and 152 in order to realize fine circuits. In addition, the insulating layers 151 and 152 may be formed of an epoxy based resin such as FR-4, Bismaleimide Triazine (BT), or the like, but are not particularly limited thereto.

The base substrate 100 may be divided into a circuit region 101 and a dummy region 102. Circuit layers may be formed in the circuit region 101. The circuit layer may include circuit patterns 120 and vias 110.

Circuit layers are not formed in the dummy region 102. In the present embodiment, the heat radiating vias 210 and 220 may be formed in the dummy region 102. The circuit layer is preferably formed by using a conventional semi-additive process (SAP), but is not necessarily limited thereto. The circuit layer may be of course formed by using a modified semi-additive process (MSAP), a subtractive method, or the like.

The heat radiating vias 210 and 220 formed in the dummy region 102 radiate the heat generated from an inside of the printed circuit board to an outside of the printed circuit board. Here, the heat radiating vias 210 and 220 may be formed together with the circuit layer by using a semi-additive process (SAP) or the like, so that a separate manufacturing process is not needed. In addition, the heat radiating vias 210 and 220 are formed of copper having very high heat conductivity, so that the heat generated from the inside of the printed circuit board may be effectively radiated to the outside of the printed circuit board.

Meanwhile, the heat radiating vias 210 and 220 may be formed along the dummy region 102. In addition, the heat radiating vias 210 and 220 may be formed in plural. In addition, the plurality of heat radiating vias 210 and 220 may be formed in a continuous circular pattern or square pattern, but the shape thereof is not particularly limited.

According to the present embodiment, the heat radiating vias 210 and 220 may be formed in a donut shape below a die attach pad 130 in the base substrate 100. Here, the heat radiating vias 210 and 220 may be narrower from an upper portion toward a lower portion of the base substrate 100. In addition, the heat radiating vias 210 and 220 may be formed such that a spaced distance between an inside wall and an outside wall thereof may be uniform. Specifically, the base substrate 100 may have the plurality of heat radiating vias 210 and 220. In addition, the spaced distance between the plurality of heat radiating vias 210 and 220 may be uniform. In addition, the plurality of heat radiating vias 210 and 220 may be classified into a plurality of groups by vertically overlapping each other.

The donut shaped heat radiating vias 210 and 220 may be formed by etching the insulating layers 151 and 152 using an etching resist (not shown) having donut-shaped patterned openings, and then filling heat radiating via holes (not shown) with an electrically conductive metal. Here, the electrically conductive metal may be copper (Cu).

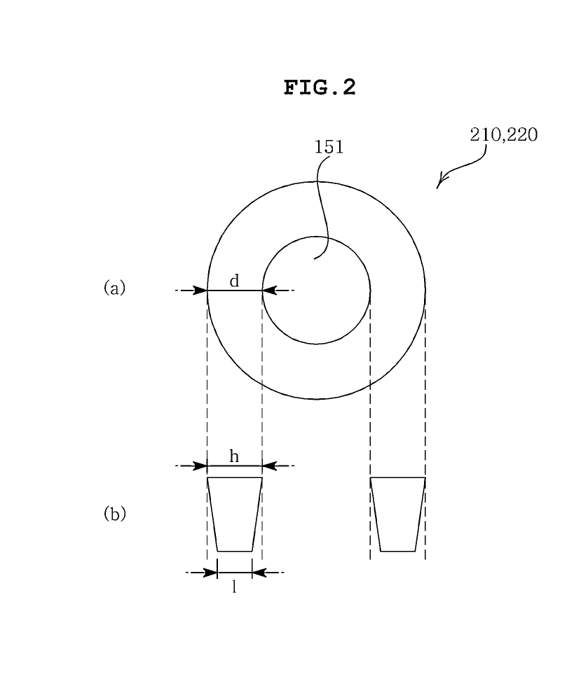

The donut-shaped heat radiating vias 210 and 220 will be described in detail with reference to FIG. 2.

FIG. 2 shows a plane view (a) and a cross-sectional view (b), showing a heat radiating via according to the preferred embodiment of the present invention.

Referring to FIG. 2, when viewed from above the printed circuit board, the heat radiating vias 210 and 220 each may be formed in a donut shape. The heat radiating vias 210 and 220 each may be formed such that an entire diameter thereof is narrower from an upper portion toward a lower portion thereof. Here, in the case where the heat radiating vias 210 and 220 are formed by etching using a laser method and then plating, a plating diameter (d) of the heat radiating vias 210 and 220 may be narrower from an upper portion (h) toward a lower portion (l) thereof. For this reason, as for the insulating layers 151 and 152 present in the centers of the heat radiating vias 210 and 220, an upper diameter may be equal to or smaller than a lower diameter.

In the prior art, the heat radiating vias 210 and 220 have a wide diameter for improvement in heat radiation characteristics, and then the entire inside of the heat radiating via holes are plated, and thus, dimples may be generated. However, in the present invention, since the plating is performed only between the inside wall and the outside wall, dimples may be prevented. Further, in the heat radiating vias 210 and 220 of the present invention, in the case where the spaced distance between the inside wall and the outside wall is kept so as to prevent dimples, the plating area may be increased by increasing the entire diameter of the heat radiating via. That is, the heat radiating vias 210 and 220 of the present invention are formed in a donut shape, so that heat radiation characteristics may be improved and dimples may be prevented.

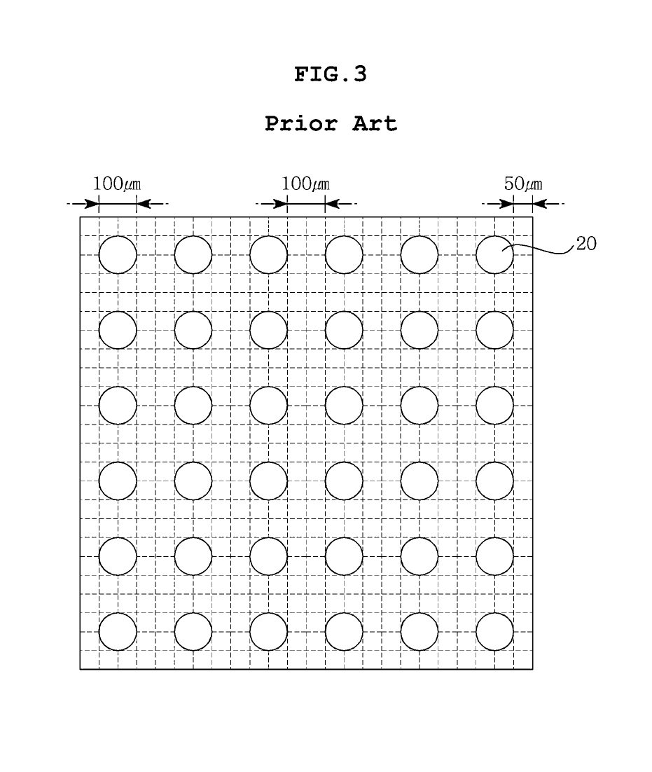

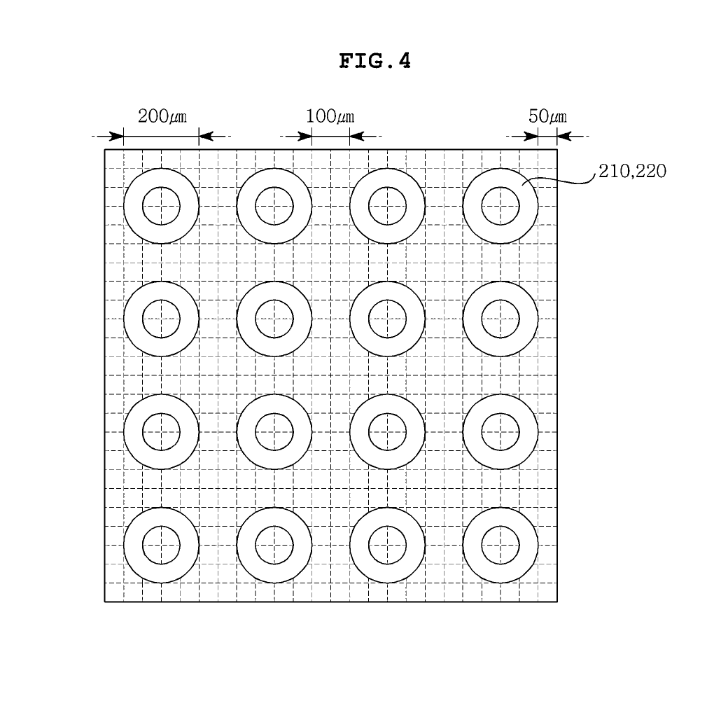

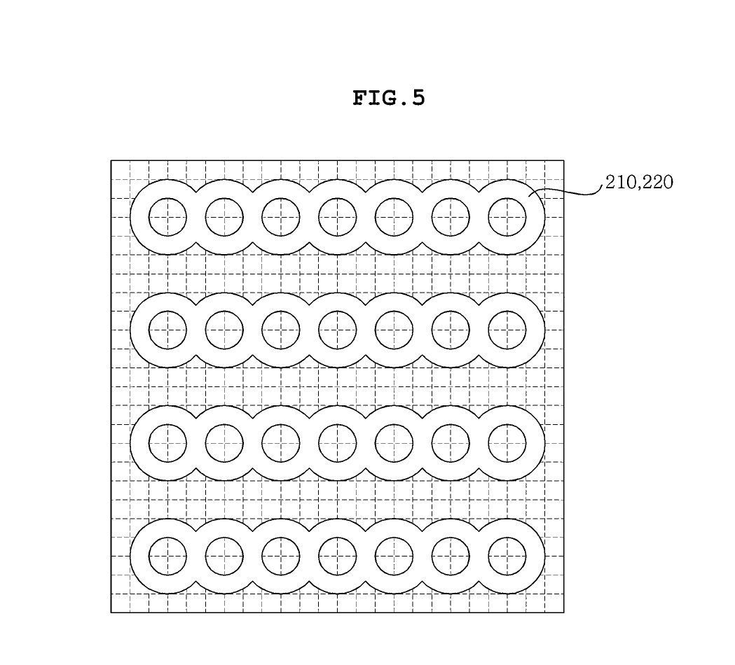

FIG. 3 is a plane view showing an arrangement state of heat radiating vias according to the prior art, FIG. 4 is a plane view showing an arrangement state of heat radiating vias according to the preferred embodiment of the present invention, and FIG. 5 is a plane view showing an arrangement state of heat radiating vias according to another preferred embodiment of the present invention. Referring to FIGS. 3 to 5, heat radiating vias 210 and 220 are shown based on a die attach pad 130 having a size of 1.2×1.2 mm.

In FIG. 3, when it is assumed that heat radiating vias 20 have a diameter of 100 μm, a spaced distance between the heat radiating vias 20 is 100 μm, and a distance from the heat radiating via 20 to an edge is 50 μm, a total of 36 heat radiating vias 20 may be formed. Based on an upper surface, the total heat radiation cross-sectional area, S1, that is, cross-sectional areas of 36 heat radiating vias 20 in sum, is calculated by Mathematical Equation 1 below.

S1=36×1.14×(50 μm)²≈0.28 mm² [Equation 1]

Meanwhile, in FIG. 4, when it is assumed that heat radiating vias 210 and 220 have a diameter of 200 μm, a spaced distance between the heat radiating vias 210 and 220 is 100 μm, and a distance from the heat radiating vias 210 and 220 to an edge is 50 μm, a total of 16 heat radiating vias 210 and 220 may be formed. Based on an upper surface, the total heat radiation cross-sectional area, S2, that is, cross-sectional areas of 16 heat radiating vias 210 and 220 in sum, is calculated by Mathematical Equation 2 below.

S2=16×3.14×((100 μm)²−(50 μm)²)≈0.38 mm² [Equation 2]

Between Mathematical Equation 1 and Mathematical Equation 2, it may be seen that the heat radiation cross-sectional area of the heat radiating vias 210 and 220 increases by about 25% in the preferred embodiment of the present invention as compared with the prior art. FIG. 4 shows a case where the spaced distance between the inside wall and the outside wall of the heat radiating vias 210 and 220 is assumed to be 50 μm. As the spaced distance between the inside wall and the outside wall increases, the heat radiation cross-sectional area of the heat radiating vias 210 and 220 further increases. For example, the cross-sectional area of the heat radiating vias 210 and 220 may be increased to 200 μm or greater. The preferred embodiment of the present invention is described by exemplifying the cross-sectional area of the heat radiating vias 210 and 220, for convenience of explanation. However, when the heat radiation vias in FIG. 3 and FIG. 4 are assumed to have the same height, the total area of the heat radiating vias may be proportional to the cross-sectional area thereof. That is, since the cross-sectional area of the heat radiating vias 210 and 220 in FIG. 4 is greater than the cross-sectional area of the heat radiating vias 20 in FIG. 3, the heat radiating vias 210 and 220 in FIG. 4 may have a larger area than the heat radiating vias 20 in FIG. 3.

When the heat generated from a semiconductor chip is transferred to a main board through the heat radiating vias 210 and 220, the amount of heat transferred is proportional to the area of the heat radiating vias 210 and 220 and thus the greater the area, the better the heat radiation efficiency.

Meanwhile, in the case where the area of the heat radiating vias 210 and 220 needs to be further increased since the heat generation amount of the semiconductor chip is very large, a plurality of heat radiating vias 210 and 220 having the same height may be formed to overlap each other as shown in FIG. 5. Here, the heat radiating vias 210 and 220 may be classified into a plurality of groups while the plurality of heat radiating vias 210 and 220 overlapping each other is considered as one group (here, the size of the heat radiating vias 210 and 220 is the same as that shown in FIG. 4). For example, in FIG. 5, the heat radiating vias 210 and 220 having the same size as those in FIG. 4 are etched, but a total of 28 heat radiating vias 210 and 220 may be formed while they are classified into 4 groups and 7 heat radiating vias 210 and 220 overlap each other for one group. Here, parts of the heat radiating vias 210 and 220 overlap each other, but since additional numbers of heat radiating vias 210 and 220 may be formed as compared with the case shown in FIG. 4, the heat radiation area is increased.

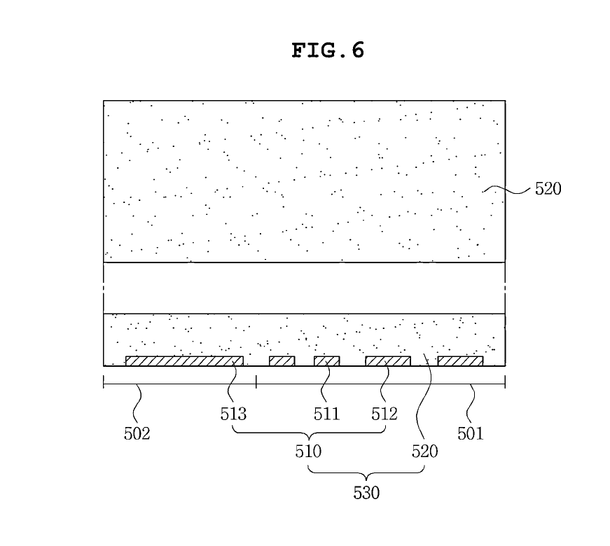

FIGS. 6 to 13 are exemplified views showing a method for manufacturing a printed circuit board according to the preferred embodiment of the present invention.

Referring to FIG. 6, a base substrate 530 is provided. The base substrate 530 may include an insulating layer 520 and an inner layer circuit layer 510. Here, the insulating layer 520 may be formed of a composite polymer resin generally used as an interlayer insulation material. For example, prepreg may be employed for the insulating layer 520, thereby making it possible to manufacture the printed circuit board thinner. Alternatively, an Ajinomoto Build up Film (ABF) may be employed for the insulating layer 520 to implement fine circuits. Besides, the insulating layer 520 may be formed by using an epoxy-based resin such as FR-4, Bismaleimide Triazine (BT), or the like, but it is not particularly limited thereto.

The base substrate 530 may be classified into a circuit region 501 and a dummy region 502. The circuit region 501 is a region in which circuit patterns for transmitting an electric signal are formed. The dummy region 502 is a region in which the circuit patterns are not formed. Dummy patterns which are formed for heat radiation may be formed in the dummy region 502. For example, the dummy region 502 may be formed at the outer side of the circuit region 501. Although FIG. 6 shows that the dummy region 502 is formed at one side of the circuit region 501, a position at which the dummy region 502 is formed is not limited thereto. For example, the dummy region 502 may be formed so that it is spaced apart from the circuit region 501 to the outside and surrounds the circuit region 501.

The inner layer circuit layer 510 may include an inner layer circuit pattern 511, an inner layer via pad 512, and an inner layer heat radiating pad 513. The inner layer circuit pattern 511 and the inner layer via pad 512 may be formed in the circuit region 501. The inner layer via pad 512 may be a pad to which vias (not shown) which are formed for the electric signal transmission is connected. The inner layer heat radiating pad 513 may be formed in the dummy region 502. The inner layer heat radiating pad 513 may be a pad to which heat radiating vias (not shown) which are formed for heat transmission is connected. The inner layer circuit layer 510 may be made of a metal. For example, the inner layer circuit layer 510 may be made of copper.

Although the preferred embodiment of the present invention shows that the base substrate 530 is formed in a single layer, for convenience of explanation, but is not limited thereto. That is, the base substrate 530 may be formed in a build-up layer having one and more layers, including the insulating layer and the circuit layer on one surface or both surfaces thereof. In addition, the base substrate 530 may have the circuit layer having one and more layers formed therein.

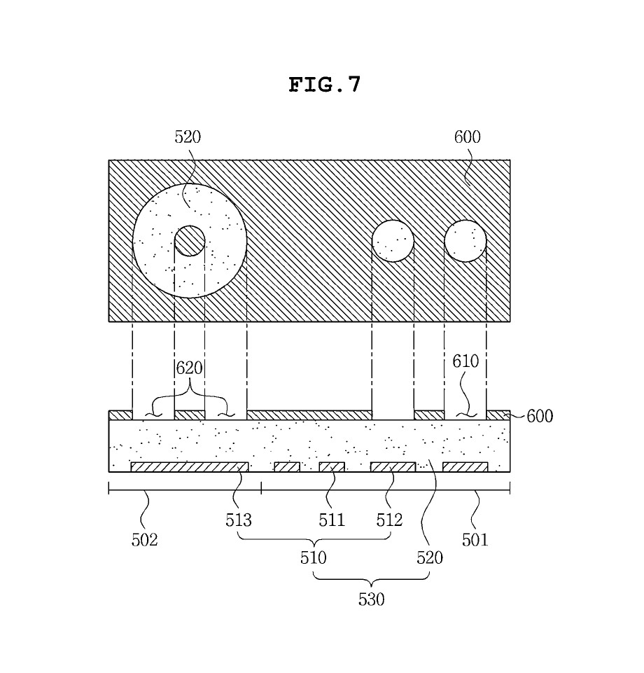

Referring to FIG. 7, an etching resist 600 may be formed on the base substrate 530.

The etching resist 600 formed in the circuit region 501 may be provided with a first etching open part 610 exposing a region in which the vias will be formed. The first etching open part 610 may have a transverse cross-section of a circular shape.

The etching resist 600 formed in the circuit region 502 may be provided with a second etching open part 620 exposing a region in which the heat radiating vias will be formed. The heat radiating via according to the preferred embodiment of the present invention may have a transverse cross-section of a donut shape. Therefore, the transverse cross-section of the second etching open part 620 of the etching resist 600 for forming the heat radiating via may have a donut shape. That is, in the etching resist 600 of the dummy region 502, a center portion having the circular shape is closed, and the second etching open part 620 may be formed so that it is spaced apart from the center portion by a predetermined distance and surrounds the center portion.

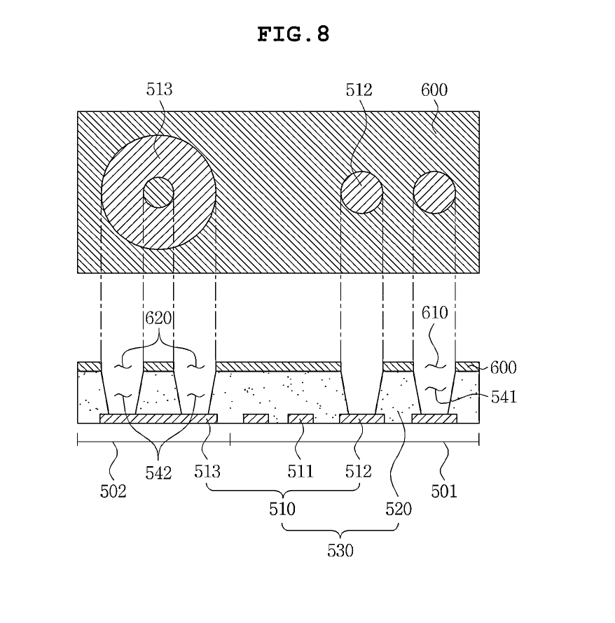

Referring to FIG. 8, a via hole 541 and a heat radiating via hole 542 may be formed in the base substrate 530.

An etching may be performed in the base substrate 530. Here, the via hole 541 having the transverse cross-section of the circular shape may be formed in the circuit region 501 by the first etching open part 610 having the circular shape of the etching resist 600.

The heat radiating via hole 542 having the transverse cross-section of the circular shape may be formed in the dummy region 502 by the second etching open part 620 having the donut shape of the etching resist 600.

The via hole 541 and the heat radiating via hole 542 may be formed by a laser etching method. At the time of laser-etching the via hole 541 and the heat radiating via hole 542, YAG laser or CO₂ laser may be used as the laser. In the case of employing the laser etching method, each diameter of the via hole 541 and the heat radiating via hole 542 may be narrower from an upper portion toward a lower portion thereof. Therefore, each diameter of the heat radiating via hole 542 having the donut shape and the insulating layer 520 which is the center portion may be larger from an upper portion toward a lower portion thereof. In addition, a spaced distance between an inner wall of the heat radiating via hole 542 and an outer wall thereof may be narrower from an upper portion toward a lower portion thereof. Even though one heat radiating via hole 542 is formed in the preferred embodiment of the present invention, a plurality of heat radiating via holes 542 may be formed by selection of a person skilled in the art. Although not shown in the drawings, the plurality of heat radiating via holes 542 may be formed so as to overlap each other.

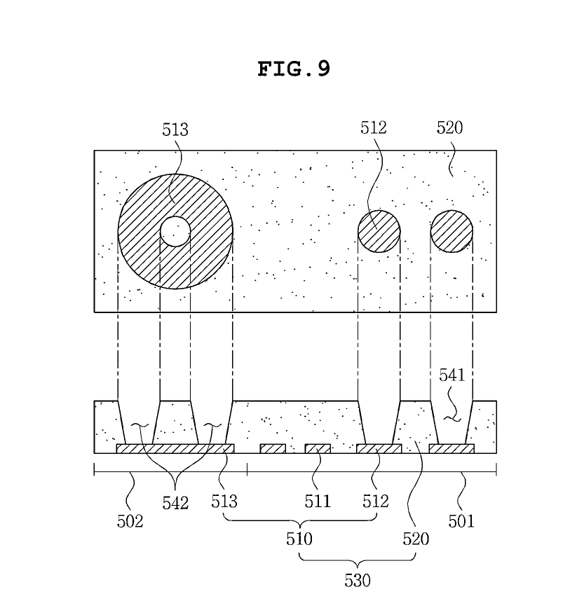

Referring to FIG. 9, after the via hole 541 and the heat radiating via hole 542 are formed in the base substrate 530, the etching resist 600 may be removed.

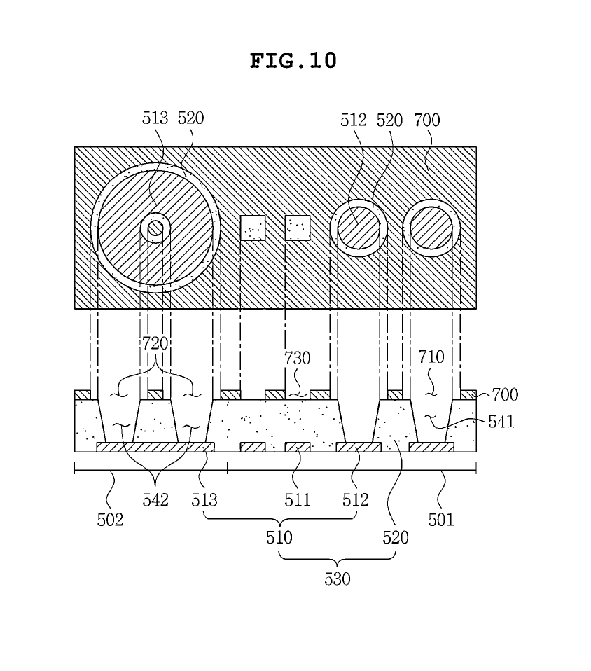

Referring to FIG. 10, a plating resist 700 may be formed on the base substrate 530. The plating resist 700 may be provided with a first plated open part 710 exposing the via hole 541. The first plating open part 710 may have a diameter larger than that of the via hole 541.

In addition, the plating resist 700 may be provided with a second plating open part 720 exposing the heat radiating via hole 542. The second plating open part 720 may have a diameter larger than that of the heat radiating via hole 542.

In addition, the plating resist 700 may be provided with a third plating open part 730 exposing a region in which an outer layer circuit pattern (not shown) will be formed.

Although not shown in the preferred embodiment of the present invention, it is obvious that a seed layer (not shown) may be formed on the base substrate 530 by an electroless plating method, before or after the plating resist 700 is formed by selection of a person skilled in the art.

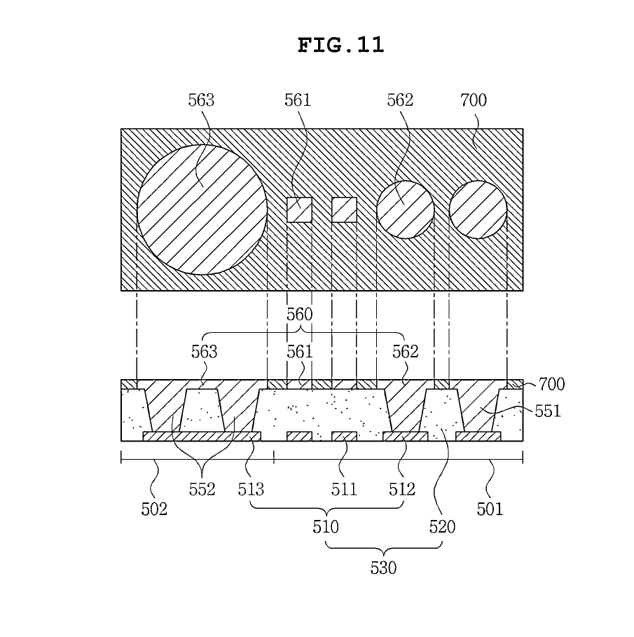

Referring to FIG. 11, the via 551, a heat radiating vias 552, and the outer layer circuit layer 560 may be formed in the base substrate 530. The outer layer circuit layer 560 may be formed by an electroplating method. The outer layer circuit layer 560 may be made of an electrically conductive material. For example, the outer layer circuit layer 560 may be made of copper.

The circuit region 501 may have via 551 formed therein by performing a plating process on the first plating open part 710. In addition, an outer layer via pad 562 may be formed on the via 551 while the via 551 are formed by the first plating open part 710 having a diameter larger than that of the via hole 541.

In addition, an outer layer circuit pattern 561 may be formed by performing the plating process on the third plating open part 730 in the circuit region 501.

An heat radiating via 552 having the transverse cross-section of a donut shape may be formed by performing the plating process on the second plating open part 720 in the dummy region 502. In addition, an outer layer heat radiating pad 563 may be formed on the heat radiating via 552 while the heat radiating vias 552 are formed by the second plating open part 720 having a diameter larger than that of the heat radiating via hole 542.

In the preferred embodiment of the present invention, it is previously described that the outer layer circuit layer 560 is made of copper. However, the material of the outer layer circuit layer 560 is not limited to the copper, and therefore, any material may be used as long as the material is generally applied to form the circuit layer. In addition, even though it is described that the outer layer circuit layer 560 is formed by the electroplating method in the preferred embodiment of the present invention, the method for forming the outer layer circuit layer 560 is not limited thereto. That is, any known methods for forming the circuit layer may be used as the method for forming the outer layer circuit layer 560.

According to the preferred embodiment of the present invention, each diameter of the via 551 and the heat radiating vias 552 may be narrower from an upper portion toward a lower portion thereof. In addition, a spaced distance between an inner wall of the heat radiating via 552 and an outer wall thereof may be narrower from an upper portion toward a lower portion thereof.

Referring to FIG. 12, after the outer layer circuit layer 560 is formed on the base substrate 530, the plating resist 700 may be removed.

Although not shown in the preferred embodiment of the present invention, in the case in which the seed layer (not shown) is formed before the outer layer circuit layer 560 is formed, the removing of the seed layer (not shown) may be further included. The removing of the seed layer (not shown) may be changed according to a position at which the seed layer (not shown) is formed.

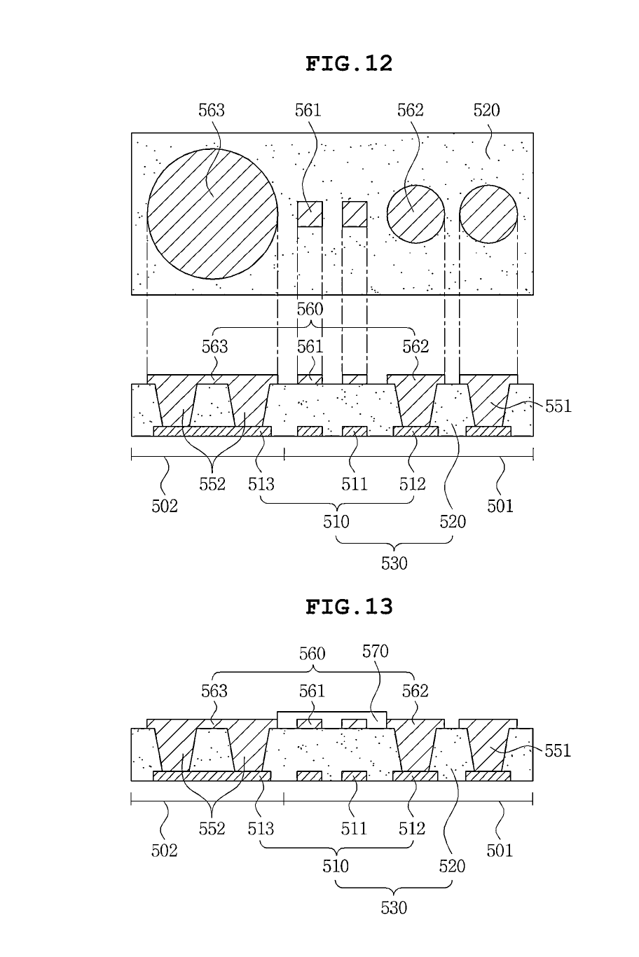

Referring to FIG. 13, the solder resist layer 570 may be formed. According to the preferred embodiment of the present invention, the solder resist layer 570 may be formed so as to bury the outer layer circuit pattern 561. The solder resist layer 570 may be formed so as to bury a pattern to be protected from the soldering process, or the like, which is subsequently performed, in addition to the outer layer circuit pattern 561.

In the method for manufacturing the printed circuit board according to FIGS. 6 to 13, the vias and the heat radiating vias may be simultaneously formed. As described above, at the time of forming the vias, the heat radiating vias are simultaneously formed, such that an additional process and additional manufacturing cost are not required.

Since the printed circuit board and the method for manufacturing the same, according to the prior art includes a base substrate including an insulating layer divided into a circuit region provided in a center thereof and a dummy region provide at an outer region of the circuit region, a circuit layer formed in the circuit region of the insulating layer and having circuit patterns and vias, and heat radiating patterns formed by filling cavities provided in the dummy region of the insulating layer, and thus, the improvement in performance of the RF module by increasing the area of the heat radiating vias may not be obtained.

However, in the preferred embodiment of the present invention, the improvement in performance of the RF module by increasing the area of the heat radiating vias may be obtained and the area of the heat radiating area may be increased, without requiring an additional process nor increasing manufacturing cost. In addition, the area of the heat radiating vias may be varied by controlling the spaced distance between the inside wall and the outside wall of the heat radiating via and the overlapping degree of the heat radiating vias, and the optimum heat radiating vias may be designed depending on characteristics of the semiconductor chip.

As set forth above, according to the printed circuit board and the method for manufacturing the same of the preferred embodiments of the present invention, the area of the heat radiating via may be increased, and thus the heat radiation efficiency may be improved.

Although the embodiments of the present invention have been disclosed for illustrative purposes, it will be appreciated that the present invention is not limited thereto, and those skilled in the art will appreciate that various modifications, additions, and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a base substrate having circuit patterns; and
heat radiating vias having a donut shape, formed in the base substrate.

2. The printed circuit board as set forth in claim 1, wherein a center of the heat radiating via is formed of an insulating layer and an outside of the insulating layer is surrounded by plating at a predetermined space.

3. The printed circuit board as set forth in claim 2, wherein a diameter of the heat radiating via is narrower from an upper portion toward a lower portion of the base substrate.

4. The printed circuit board as set forth in claim 1, wherein a spaced distance between an inside wall and an outside wall of the heat radiating via is narrower from an upper portion toward a lower portion thereof.

5. The printed circuit board as set forth in claim 1, wherein the base substrate has one or more heat radiating vias formed thereon.

6. The printed circuit board as set forth in claim 1, wherein a plurality of heat radiating vias are formed on the same line of the base substrate and classified into a plurality of groups while at least two of the plurality of heat radiating vias overlap each other for each group.

7. A method for manufacturing a printed circuit board, the method comprising:
preparing a base substrate having circuit patterns; and
forming heat radiating vias having a donut shape in the base substrate.

8. The method as set forth in claim 7, wherein the forming of the heat radiating vias includes:
preparing an etching resist, having openings formed in the donut shape, on the base substrate;
etching the base substrate to form heat radiating via holes having a donut shape; and
plating inside of the heat radiating via holes to form heat radiating vias.

9. The method as set forth in claim 8, wherein a diameter of the heat radiating via hole is narrower from an upper portion toward a lower portion of the base substrate.

10. The method as set forth in claim 7, wherein in the forming of the heat radiating vias, a spaced distance between an inside wall and an outside wall of each of the heat radiating vias is narrower from an upper portion toward a lower portion thereof.

11. The method as set forth in claim 7, wherein in the forming of the heat radiating vias, one or more heat radiating vias are formed.

12. The method as set forth in claim 7, wherein in the forming of the heat radiating vias, a plurality of heat radiating vias are formed on the same line of the base substrate and classified into a plurality of groups while at least two of the plurality of heat radiating vias overlap each other for each group.

13. The method as set forth in claim 7, further comprising, after the preparing of the base substrate, forming vias.

14. The method as set forth in claim 13, wherein the forming of the vias and the forming of the heat radiating vias are simultaneously performed.
